(19) United States
(12) Patent Application Publication
(10) Pub. No.: US 2017/0117021 A1
(43) Pub. Date: Apr. 27, 2017

(54) MULTI-LEVEL DATA FOLDING

(71) Applicant: SANDISK TECHNOLOGIES INC., Plano, TX (US)

(72) Inventors: NIAN NILES YANG, MOUNTAIN VIEW, CA (US); CHRIS NGA YEE AVILA, SARATOGA, CA (US)

(73) Assignee: SANDISK TECHNOLOGIES INC.

(21) Appl. No.: 14/919,289

(22) Filed: Oct. 21, 2015

(51) Int. Cl. G11C 7/10; G11C 11/56

(52) U.S. Cl. CPC G11C 7/10; G11C 11/56

(57) ABSTRACT

A device includes a memory including a first set of storage elements and a second set of storage elements. The device further includes circuitry coupled to the memory and configured to perform a data folding operation to fold second data from the second set of storage elements with respect to first data stored at the first set of storage elements. Each storage element of the first set of storage elements is designated to store at least three bits per storage element, and each storage element of the second set of storage elements is designated to store at least two bits per storage element.

### FIELD OF THE DISCLOSURE

The present disclosure is generally related to multi-level data storage.

### BACKGROUND

As data storage device technology improves, data storage devices are designed to store an increased amount of data. To increase the amount of stored data, a data storage device may include storage elements capable of storing charges that represent multiple bits of data per storage element (e.g., multi-level cell (MLC) data). For example, a data storage device may include storage elements capable of storing second level data (“X2” data), third level data (“X3” data), fourth level data (“X4” data), or higher level data. To illustrate, X2 data may be stored as two bits per storage element, X3 data may be stored as three bits per storage element, and X4 data may be stored as four bits per storage element. As the number of bits stored per storage element increases, the programming efficiency of programming MLC data to storage elements decreases. The decreased programming efficiency also causes reduced performance and reliability of the storage elements. For example, the programming efficiency of programming X4 data to storage elements is less than the programming efficiency of programming single-level cell (SLC) data (e.g., data stored as one bit per storage element) to storage elements. Due to the reduced programming efficiency, the storage elements designated to store X4 data have reduced performance and reliability as compared to storage elements designated to store SLC data.

### BRIEF DESCRIPTION OF THE DRAWINGS

FIG. 1 is a block diagram of a particular illustrative example of a system configured to perform multi-level data write operations and a subsequent data folding operation;

FIG. 2 is a cell voltage distribution (CVD) diagram that illustrates states corresponding to storage elements prior to and subsequent to a data folding operation;

FIG. 3 is a diagram of a first example of performing a data folding operation on second multi-level data with respect to first multi-level data;

FIG. 4 is a diagram of a second example of performing a data folding operation on second multi-level data with respect to first multi-level data;

FIG. 5 is a diagram of an example of a data folding operation used to store fourth level (X4) data;

FIG. 6 illustrates CVD diagrams that represent states corresponding to storage elements after a first half-window programming operation and after a second half-window programming operation;

FIG. 7 illustrates CVD diagrams that represent states corresponding to storage elements prior to, during, and subsequent to a partial erase operation;

FIG. 8 illustrates a table indicating permissible next programming operations or erase operations based on operations performed on a set of storage elements; and

FIG. 9 is a flow diagram that illustrates a particular example of a method of performing a write operation to increase a number of bits stored at a set of storage cells.

### DETAILED DESCRIPTION

Particular implementations are described with reference to the drawings. In the description, common features are designated by common reference numbers throughout the drawings. As used herein, “exemplary” may indicate an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term).

Storage elements are capable of storing multi-level cell (MLC) data and single-level cell (SLC) data. MLC data refers to data stored as multiple bits per storage element, and SLC data refers to data stored as one bit per storage element. Data having a particular level (e.g., a particular number of bits to be stored per storage element) may also be referred to as “Xn” data, where n is a positive integer representing the particular level (e.g., the number of bits to be stored per storage element). For example, second level data (“X2” data) may be stored as two bits per storage element, third level data (“X3” data) may be stored as three bits per storage element, and fourth level data (“X4” data) may be stored as four bits per storage element. These examples are not intended to be limiting, and in other implementations n may be a positive integer greater than four. As described herein, a set of storage elements may be designated to store data having a particular level. However, as part of a process to store data having the particular level at the set of storage elements, the set of storage elements may temporarily store data having a lower level. For example, a set of storage elements may be designated to store X4 data, and during a process of writing X4 data to the set of storage elements, the set of storage elements may temporarily store X2 data (e.g., prior to performance of a data folding operation, as further described herein).

The present disclosure provides systems, devices, and methods of performing data folding operations to store data having a particular level (e.g., a particular number of bits stored per storage element). As described herein, first data (e.g., first X2 data) may be written to a first set of storage elements, second data (e.g., second X2 data) may be written to a second set of storage elements, and a data folding operation may be performed on the second data with respect to the first data to store folded data (e.g., X4 data) in the first set of storage elements. Performing the two multi-level write operations and the data folding operation may be faster and more efficient than storing the higher level data (e.g., the X4 data) directly to the first set of storage elements (e.g., performing an X4 data write operation).

Additionally, the present disclosure describes wear-reducing operations, such as a half-window programming operation, also referred to as a half-window write operation, and a partial erase operation. As compared to a write operation (e.g., a “full” write operation), that programs states of storage elements to within a voltage window (e.g., a voltage range), a half-window write operation may program states of the set of storage elements to one of multiple voltage sub-windows (e.g., a sub-ranges) of the voltage window associated with the write operation. After using the half-window write operation to write first data to the set of storage elements, a second half-window write operation may be performed at the set of storage elements to write second data by setting states of the storage elements to within a second voltage sub-window. The two half-window write operations may be performed at the set of storage elements before an erase operation is needed (as compared to a single write operation prior to an erase operation).

As another example of a wear-reducing operation, the present disclosure describes a partial erase operation. The partial erase operation may be performed to set a set of storage elements to a partial erase state having a larger voltage range than an erase state associated with an erase operation (e.g., a “full” erase operation). Performing the partial erase operation may use a lower voltage and may be faster than a full erase operation. Thus, use of partial erase operations and half-window write operations reduces a number of full erase operations that are performed to storage elements, which slows wear to the storage elements and increases longevity of a memory. In some implementations, the data folding operations described herein may be used in combination with the half-window write operations and/or the partial erase operations. In other implementations, the half-window write operations and/or the partial erase operations may be used independently from the data folding operations.

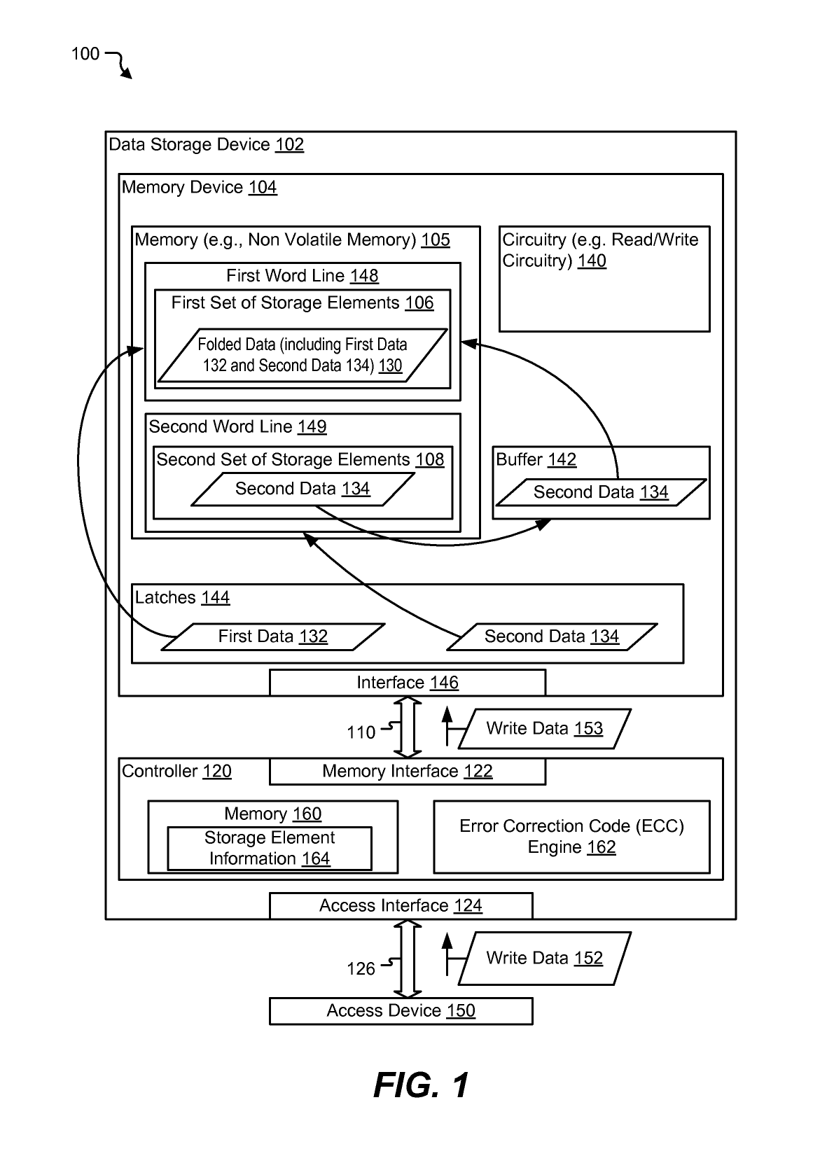

Referring to FIG. 1, a particular illustrative example of a device 100 is shown. The device 100 includes a data storage device 102 coupled via a communication path 126 to an access device 150. The communication path 126 may be a bus or a wireless connection, as non-limiting examples. The data storage device 102 may include an access interface 124 that enables communication via the communication path 126, such as when the access interface 124 is communicatively coupled to the access device 150. In some implementations, the data storage device 102 may be embedded within the access device 150, such as in accordance with a Joint Electron Devices Engineering Council (JEDEC) Solid State Technology Association Universal Flash Storage (UFS) configuration. Alternatively, the data storage device 102 may be removable from the access device 150 (i.e., “removably” coupled to the access device 150). As an example, the data storage device 102 may be removably coupled to the access device 150 in accordance with a removable universal serial bus (USB) configuration. In some implementations, the data storage device 102 may include or correspond to a solid state drive (SSD) which may be included in, or distinct from (and accessible to), the access device 150. For example, the data storage device 102 may include or correspond to an SSD, which may be used as an embedded storage drive (e.g., a mobile embedded storage drive), an enterprise storage drive (ESD), a client storage device, or a cloud storage drive, as illustrative, non-limiting examples. In some implementations, the data storage device 102 may be coupled to the access device 150 indirectly, e.g., via a network. For example, the data storage device 102 may be a network-attached storage (NAS) device or a component (e.g., a solid-state drive (SSD) device) of a data center storage system, an enterprise storage system, or a storage area network.

In some implementations, the data storage device 102 may be configured to be coupled to the access device 150 as embedded memory, such as eMMC® (trademark of JEDEC Solid State Technology Association, Arlington, Va.) and eSD, as illustrative examples. To illustrate, the data storage device 102 may correspond to an eMMC (embedded MultiMedia Card) device. As another example, the data storage device 102 may correspond to a memory card, such as a Secure Digital (SD®) card, a microSD® card, a miniSD™ card (trademarks of SD-3C LLC, Wilmington, Del.), a MultiMediaCard™ (MMC™) card (trademark of JEDEC Solid State Technology Association, Arlington, Va.), or a CompactFlash® (CF) card (trademark of SanDisk Corporation, Milpitas, Calif.). The data storage device 102 may operate in compliance with a JEDEC industry specification. For example, the data storage device 102 may operate in compliance with a JEDEC eMMC specification, a JEDEC Universal Flash Storage (UFS) specification, one or more other specifications, or a combination thereof.

In some implementations, the data storage device 102 and the access device 150 may be configured to communicate using one or more protocols, such as an eMMC protocol, a universal flash storage (UFS) protocol, a universal serial bus (USB) protocol, a serial advanced technology attachment (SATA) protocol, and/or another protocol, as illustrative, non-limiting examples. The one or more protocols may include a standardized protocol and/or a non-standardized protocol, such as a proprietary protocol. In some implementations, the data storage device 102 and the access device 150 may be configured to communicate using dual channel communication (e.g., both devices may issue and receive commands from the other device).

The access device 150 may include a memory interface (not shown) and may be configured to communicate with the data storage device 102 via the memory interface to read data from and write data to a memory 105 of the data storage device 102. For example, the access device 150 may operate in compliance with a Joint Electron Devices Engineering Council (JEDEC) industry specification, such as a Universal Flash Storage (UFS) Access Controller Interface specification. As other examples, the access device 150 may operate in compliance with one or more other specifications, such as a Secure Digital (SD) Access Controller specification, as an illustrative, non-limiting example. The access device 150 may communicate with the memory 105 in accordance with any other suitable communication protocol.

The access device 150 may include a processor and a memory. The memory may be configured to store data and/or instructions that are executable by the processor. The memory may be a single memory or may include multiple memories, such as one or more non-volatile memories, one or more volatile memories, or a combination thereof. The access device 150 may issue one or more commands to the data storage device 102, such as one or more requests to erase data, read data from, or write data to the data storage device 102. For example, the access device 150 may be configured to provide data to be stored at the data storage device 102 or to request data to be read from the data storage device 102. The access device 150 may include a mobile telephone, a music player, a video player, a gaming console, an electronic book reader, a personal digital assistant (PDA), a computer, such as a laptop computer or notebook computer, a network computer, a server, any other electronic device, or any combination thereof, as illustrative, non-limiting examples.

The data storage device 102 includes a memory device 104 and a controller 120. The controller 120 is coupled to the memory device 104 via a bus 110, an interface (e.g., interface circuitry, such as a memory interface 122), another structure, or a combination thereof. The controller 120 and the memory device 104 may exchange information via the bus 110, the memory interface 122, an interface 146 within the memory device 104, or a combination thereof. For example, one or more of write data, read data, and other data or instructions may be exchanged between the controller 120 and the memory device 104 via the bus 110, the memory interface 122, the interface 146, or a combination thereof.

The controller 120 includes a controller memory 160 that stores storage element information 164. The storage element information 164 may indicate information for sets of storage elements of the memory device 104, as further described herein. As one example, the storage element information 164 may indicate a recent operation performed at a set of storage elements, a number of bits stored per storage element of the set of storage elements, or a combination thereof.

The controller 120 also includes an error correction code (ECC) engine 162. The ECC engine 162 may be configured to perform ECC processing on input data, such as write data 152 received by the controller 120 from the access device 150, to generate one or more ECC codewords. For example, the ECC engine 162 may process the input data using an ECC encoding technique, such as a Reed-Solomon encoding technique, a Bose-Chaudhuri-Hocquenghem (BCH) encoding technique, a low-density parity check (LDPC) encoding technique, a turbo encoding technique, one or more other ECC encoding techniques, or a combination thereof, as illustrative, non-limiting examples. To illustrate, the ECC engine 162 may be configured to process the write data 152 to generate the encoded write data 153 (e.g., one or more ECC codewords).

The ECC engine 162 may also be configured to receive data, such as one or more ECC codewords, from the memory device 104 and to process the received data based on one or more ECC decoding techniques to generate output data. The output data decoded output data may be provided to the access device 150, for example in response to a read command from the access device 150. In some implementations, the ECC engine 162 may include an encoder configured to generate ECC codewords based on input data and a decoder configured to generate output data based on received ECC codewords. In other implementations, the ECC engine 162 does not include a separate encoded and decoder.

The memory device 104 includes latches 144, a buffer 142, circuitry 140, and a memory 105. The latches 144 may be configured to store data received from the controller 120 in one or more portions. For example, the latches 144 may be configured to store a first portion of the encoded write data 153 as the first data 132 and a second portion of the encoded write data 153 as the second data 134. The first data 132 and the second data 134 may be stored at the latches 144 during performance of write operations and a data folding operation, as further described herein.

The memory 105 may include multiple storage elements configured to store data. In a particular implementation, the memory device 104 includes a non-volatile memory device, and the memory 105 includes a non-volatile memory, such as a Flash memory. The memory 105 may have a two-dimensional (2D) memory configuration. Alternatively, the memory 105 may have another configuration, such as a three-dimensional (3D) memory configuration. For example, the memory 105 may include a three-dimensional (3D) memory configuration that is monolithically formed in one or more physical levels of arrays of memory cells (e.g., storage elements) having an active area disposed above a silicon substrate. In other implementations, the memory 105 may include a volatile memory. The memory 105 may include one memory die or multiple memory dies.

In a particular implementation, the first set of storage elements 106 and the second set of storage elements 108 are designated to store MLC data. A voltage stored at a storage element may correspond to a state of the storage element, and the state may represent multiple bits of data. For example, a storage element designated to store second level data (X2 data) may have one of four states that represent two bits of data, a storage element designated to store third level data (X3 data) may have one of nine states that represent three bits of data, and a storage element designated to store fourth level data (X4 data) may have one of sixteen states that represent four bits of data. The above-described examples are not intended to be limiting, and the first set of storage elements 106 and the second set of storage elements 108 may be designated to store n bits of data per storage element, where n is a positive integer greater than one.

The memory 105 may store data in multiple regions, such as a first set of storage elements 106 and a second set of storage elements 108. In a particular implementation, the first set of storage elements 106 is accessible via a first word line 148, and the second set of storage elements 108 is accessible via a second word line 149. In other implementations, the first set of storage elements 106 and the second set of storage elements 108 may include other groups of storage elements. For example, the first set of storage elements 106 and the second set of storage elements 108 may include pages of memory, blocks of memory, zones of memory, planes of memory, dies of memory, meta-planes of memory, or other groups of storage elements. The first set of storage elements 106 are designated to store at least three bits of data per storage element, and the second set of storage elements 108 are designated to store at least two bits of data per storage element. Although storage elements may be designated to store up to a particular number of bits per storage element, the storage elements may temporarily store less than the particular number of bits per storage element if lower level data is written to the storage elements. For example, storage elements designated to store up to four bits per storage element may store fewer than four bits of data per storage elements, such as by temporarily storing X2 data or X3 data.

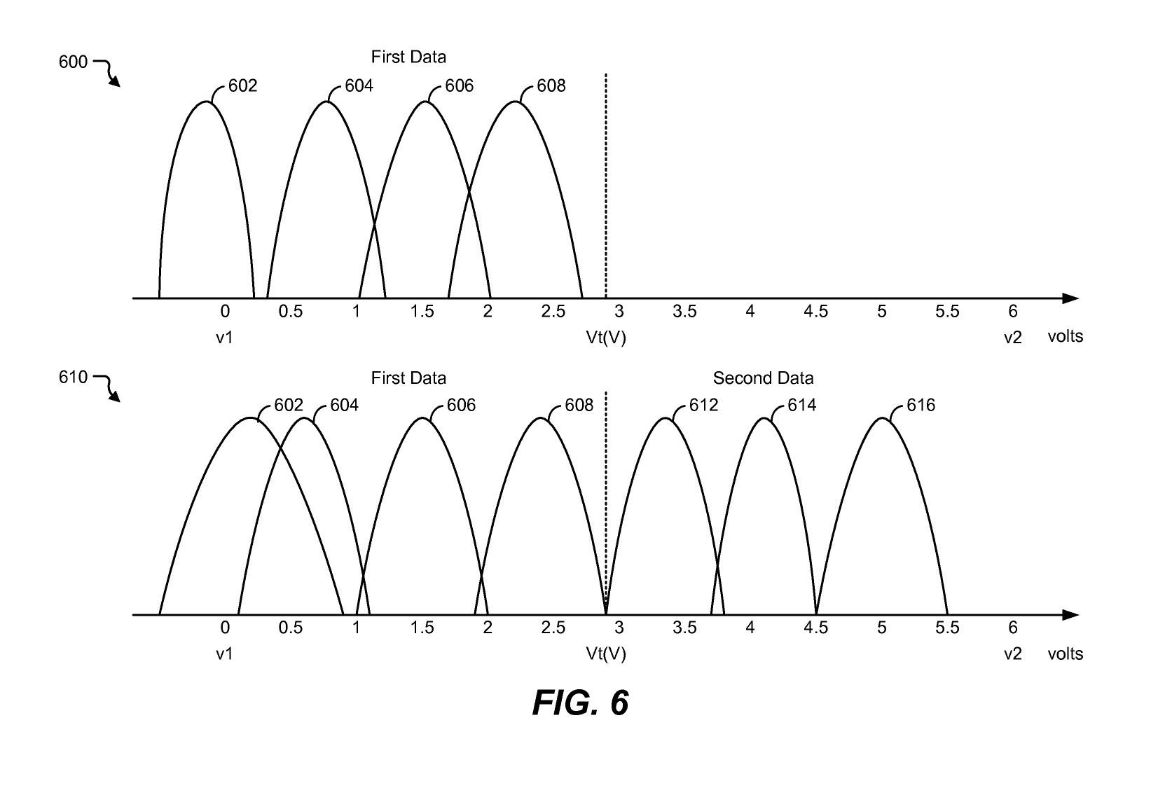

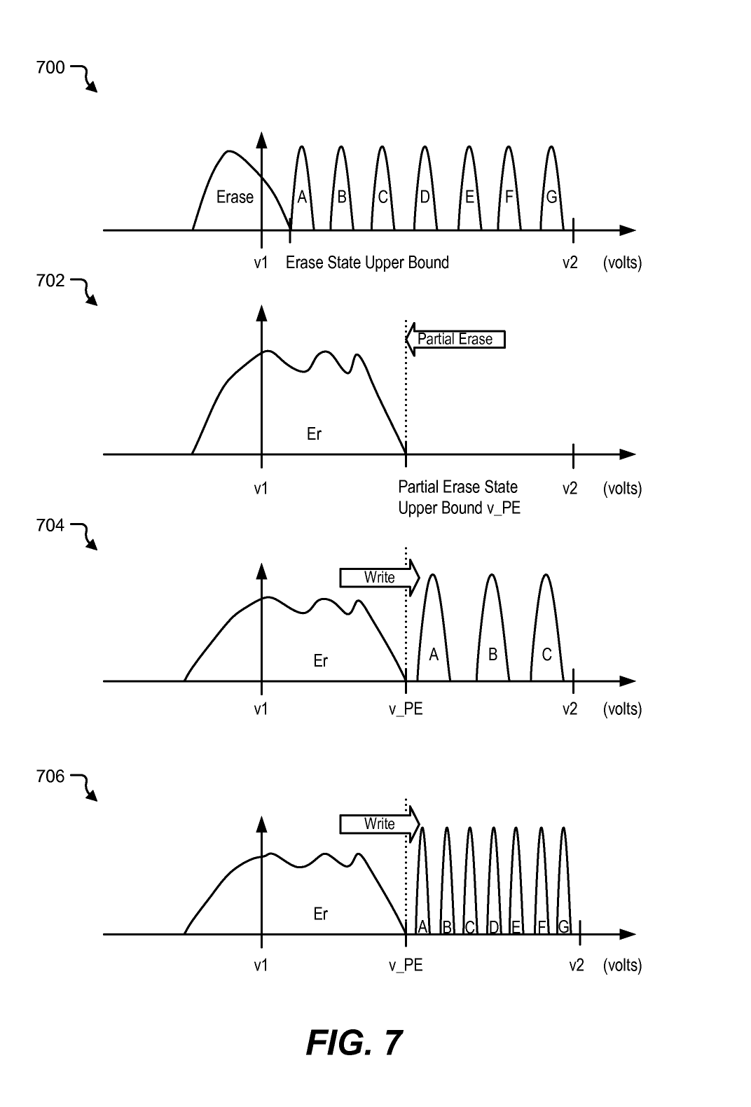

The memory device 104 further includes the buffer 142 and the circuitry 140 coupled to the memory 105. The buffer 142 is configured to store data, such as the second data 134 as illustrated. For example, the buffer 142 may store data during performance of an operation at the memory 105, such as a data folding operation, as further described herein. The buffer 142 may be a first in, first out write buffer or any other type of buffer capable of temporarily storing data. In a particular implementation, data (e.g., the second data 134) may be read from the second set of storage elements 108 into the buffer 142 during a data folding operation. The data may be provided from the buffer 142 to the ECC engine 162 for ECC processing, and after the ECC processing is complete, a representation of the data (e.g., ECC processed data) may be provided to the buffer 142 for use in the data folding operation, as further described herein. The circuitry 140 may be read/write circuitry, as illustrated in FIG. 1. The circuitry 140 may be configured to perform operations at the memory 105, such as read operations, write operations, data folding operations, erase operations, partial erase operations, half-window write operations, other operations, or a combination thereof. Half-window write operations are described with reference to FIG. 6, and partial erase operations are described with reference to FIG. 7.

During operation, the controller 120 of the data storage device 102 receives the write data 152 from the access device 150. In response to receiving the write data 152, the controller 120 may communicate the write data 152 to the ECC engine 162. The ECC engine 162 may perform an error correction code process on the write data 152 to generate encoded write data 153. The controller 120 may determine to store the encoded write data 153 as MLC data having a particular level at the first set of storage elements 106. To increase efficiency, the controller 120 may be configured to initiate two write operations and a data fold operation instead of a write operation for data having the particular level. To begin, the controller 120 may issue two write instructions to the memory device 104, and the write instructions may write data having a lower level than the particular level. For example, the controller 120 may issue a first write command indicating a first portion of the encoded write data 153, an address of the first set of storage elements 106, a size of the data to be written, and a number of bits per storage element to be stored. The controller 120 may issue a second write instruction indicating a second portion of the encoded write data 153, an address of the second set of storage elements 108, a size of the data to be written, and a number of bits per storage element to be stored. The controller 120 may be configured to break up the encoded write data 153 into the first portion and the second portion, or to indicate the data corresponding to each portion, such that the portions may be used in a data folding operation to store data having the particular level.

The controller 120 may communicate the encoded write data 153 (e.g., as part of or in addition to the two write instructions) to the memory device 104 as write data. The encoded write data 153 may include or be implemented as a set of ECC codewords. The encoded write data 153 may include multiple ECC codewords and the ECC multiple codewords may be stored in the latches 144. For example, a portion of the encoded write data 153 to be stored in the first set of storage elements 106 may be stored in the latches 144 as the first data 132, and a portion of the encoded write data 153 to be stored in the second set of storage elements 108 may be stored in the latches 144 as the second data 134. In a particular implementation, the first data 132 may be a first ECC codeword and the second data 134 may be a second ECC codeword. The first data 132 may be written from the latches 144 to the first set of storage elements 106 and the second data 134 may be written from the latches 144 to the second set of storage elements 108. For example, the circuitry 140 may cause the first data 132 and the second data 134 to be written from the latches 144 to the first set of storage elements 106 and the second set of storage elements 108, respectively. Although the latches 144 are illustrated as storing the first data 132 and the second data 134 concurrently, in other implementations the latches 144 may store the first data 132 and the second data 134 in series. For example, the first data 132 may be written to the first set of storage elements 106 prior to the second data 134 being stored in the latches 144.

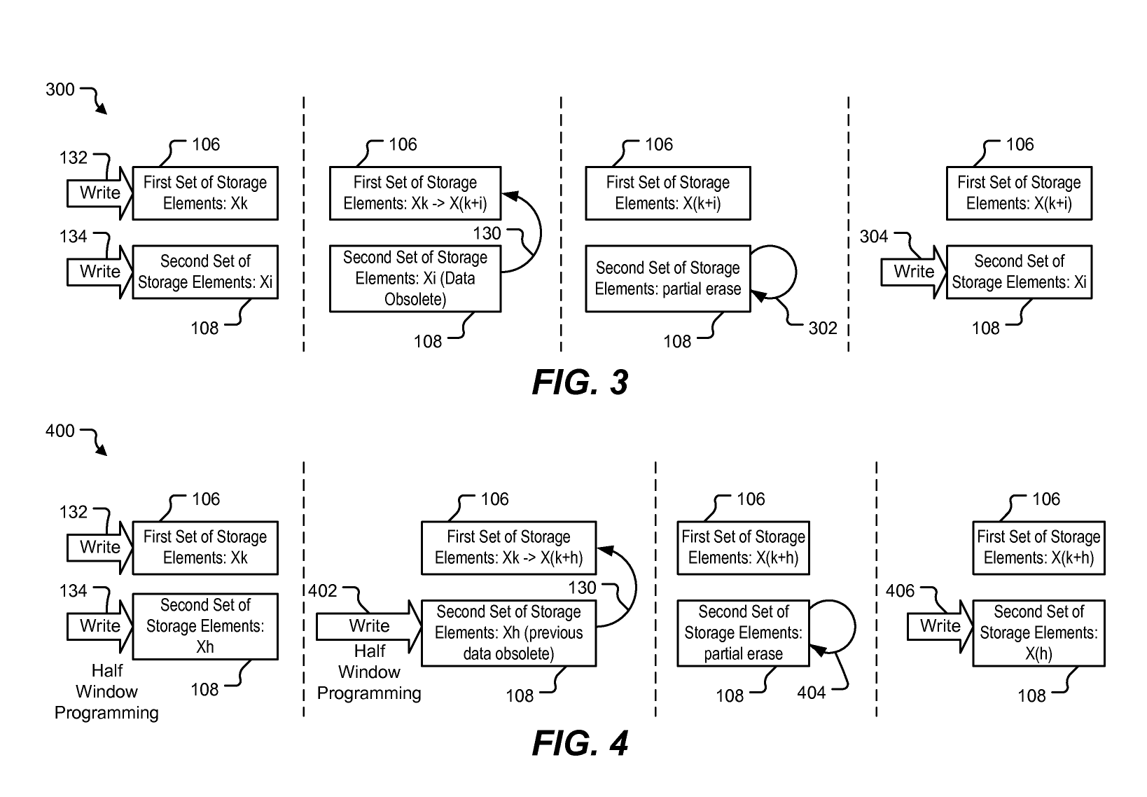

In a particular implementation, the first data 132 may be written to the first set of storage elements 106 using a write operation. The second data 134 may be written to the second set of storage elements 108 using a half-window write operation. When the second data 134 is written using the half-window write operation, states of the second set of storage elements 108 may be distributed among a first voltage sub-window (e.g., a subrange) of a voltage window associated with a write operation. A second half-window write operation may be used to overwrite the second data 134 without performing an erase operation, as further described with reference to FIGS. 3 and 4. Additional details of the half-window write operation are further described with reference to FIG. 6. In an alternate implementation, the second data 134 may be written using a write operation (e.g., a full write operation).

After completion of the two write operations, the controller 120 may initiate a data folding operation at the memory device 104. As explained above, to write multi-level data having a particular level (Xn) to the first set of storage elements 106, one or more multi-level write operations may be performed at the first set of storage elements 106 and the second set of storage elements 108, followed by performing a data folding operation to fold the second data 134 with respect to the first data 132. The data folding operation may include writing the second data 134 to the first set of storage elements 106 without overwriting the first data 132. The buffer 142 may be used to perform the data folding operation. To illustrate, the second data 134 may be retrieved from the second set of storage elements 108 and may be written to the buffer 142. In a particular implementation, the second data 134 may be provided from the buffer 142 to the ECC engine 162 (e.g., via the interface 146, the bus 110, and the memory interface 122) for ECC processing. After the second data 134 is processed (e.g., one or more errors are corrected) by the ECC engine 162, a representation of the second data 134 (e.g., ECC processed data) may be stored at the buffer 142. The second data 134 (or the representation of the second data 134) from the buffer 142 may be combined with the first data 132 by performing a folding operation with the first data 132 to generate folded data 130, as illustrated in the first set of storage elements 106. A data folding operation may also be referred to as an inter-block write operation.

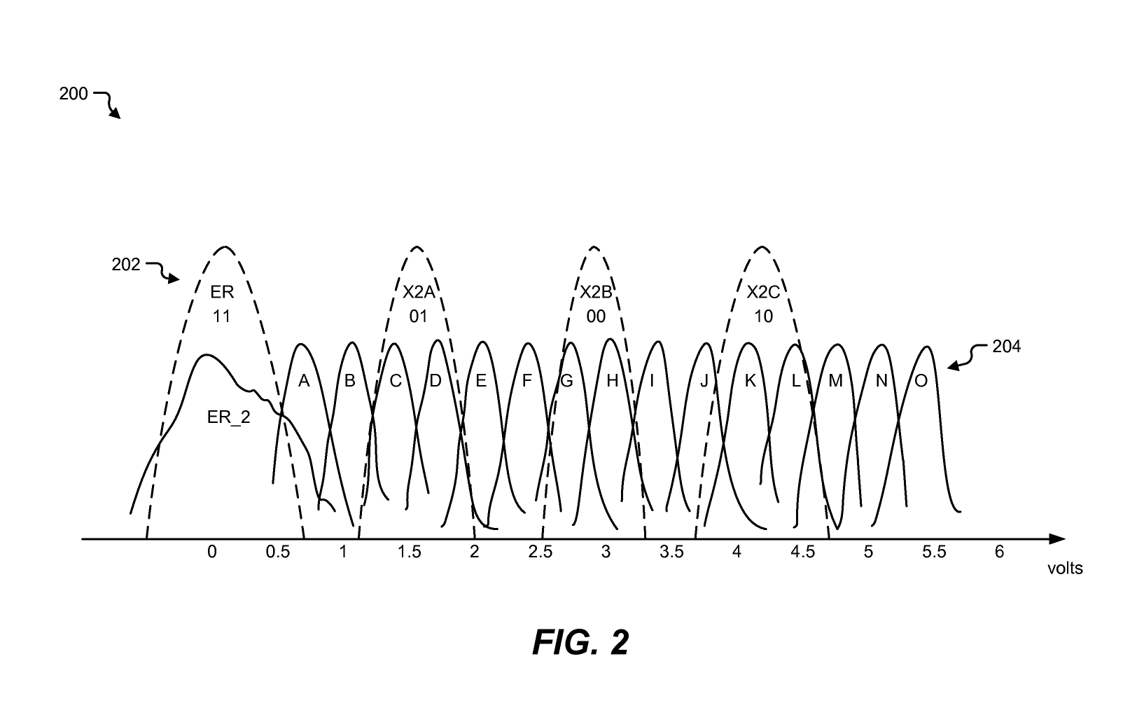

The data folding operation may maintain or increase voltages stored at the first set of storage elements 106 based on the second data 134. FIG. 2 illustrates changes in states (e.g., voltages) at storage elements caused by the data folding operation, as shown in a cell voltage distribution (CVD) diagram 200. The CVD diagram 200 illustrates states corresponding to the storage elements prior to and subsequent to a data folding operation. For example, the CVD diagram 200 illustrates states associated with the first data 132 and states associated with the folded data 130 of FIG. 1. The voltages may be distributed within a voltage window (e.g., between a lower bound and an upper bound). In the example illustrated in FIG. 2, the lower bound is approximately zero volts, and the upper bound is approximately six volts. In other implementations, the lower bound and the upper bound may be other voltages.

A group of states 202 corresponding to the first data 132 includes four states. Each state is associated with a voltage range of a storage element. For example, a storage element having a particular state stores a voltage that is within the corresponding voltage range. As illustrated in FIG. 2, the first group of states 202 includes an erase state, an X2A state, an X2B state, and an X2C state. In the example illustrated in FIG. 2, the first data 132 is X2 data (e.g., data stored as two bits per storage element). In other implementations, the first group of states 202 may include more than four states, and the first data 132 may be a different level of data. Although described as states corresponding to a write operation, in some implementations, the states may be offset to the left in the CVD diagram 200 as compared to states resulting from a write operation that is not used in a data folding operation. Such offset may be selected to maintain a voltage range between an upper bound of the highest voltage state (e.g., X2C) and the upper bound of the voltage window (e.g., six volts in FIG. 2) that is sufficiently large to include higher level data states, as further described below.

FIG. 2 also illustrates a second group of states 204 corresponding to the folded data 130. The second group of states 204 includes sixteen states, an erase state ER_2, and states A-O. In the example illustrated in FIG. 2, the folded data 130 is X4 data (e.g., data stored as four bits per storage element). In other implementations, the second group of states 204 may include a different number of states than sixteen, and the folded data 130 may be a different level of data.

When the data folding operation is performed to fold the second data 134 of FIG. 1 with respect to the first data 132 to generate the folded data 130, states of the first set of storage elements 106 (within the first group of states 202) are converted to states within the second group of states 204 by application of one or more write voltages during the data folding operation. For example, a storage element having the ER state may be converted to one of the ER_2 state and the states A-C, a storage element having the X2A state may be converted to one of the states D-G, a storage element having the X2B state may be converted to one of the states H-K, and a storage element having the X2C state may be converted to one of the states L-O. Because each of the state conversions may be performed by maintaining or increasing a voltage of a particular storage element, and not decreasing the voltage, data folding may be performed without overwriting previously stored data. As an example, if a storage element has the X2A state prior to folding, the voltage of the storage element may be maintained or increased (based on the second data 134) to be a voltage corresponding to state D, state E, state F, or state G. In this manner, the state of the storage element after the data folding operation is a function of the first data 132 and the second data 134 (e.g., the first data 132 is not overwritten).

To illustrate, the ER state may correspond to data having the value 11, the X2A state may correspond to data having the value 10, the X2B state may correspond to data having the value 00, and the X2C state may correspond to data having the value 01. In a first example, after the data folding operation, the second group of states 204 may correspond to four bit data having the format xyxy, where x are bits corresponding to the second data 134, and y are bits corresponding to the first data 132 (e.g., the first group of states 202). In this example, X2C is converted to L (0100), M (0110), N (1110), and O (1100), X2B is converted to H (0000), I (0010), J (1010), and K (1000), X2A is converted to D (0001), E (0011), F (1011), and G (1001), and Er is converted to Er_2 (1111), A (0111), B (0101), and C (1101). In a second example, after the data folding operation, the second group of states 204 may correspond to four bit data having the format xxyy, where x are bits corresponding to the second data 134, and y are bits corresponding to the first data 132 (e.g., the first group of states 202). In this example, X2C is converted to L (0110), M (0010), N (1010), and O (1110), X2B is converted to H (1100), I (1000), J (0000), and K (0100), X2A is converted to D (0101), E (0001), F (1001), and G (1101), and Er is converted to Er_2 (1111), A (1011), B (0011), and C (0111). Thus, the first data 132 may be converted to the folded data 130 by folding the second data 134 with respect to the first data 132, and the first data 132 is not overwritten by performance of the data folding operation.

Returning to FIG. 1, because the first data 132 has a lower level than a highest level of data capable of being stored at the first set of storage elements 106 (e.g., the first data 132 is X2 data and the first set of storage elements are capable of storing four bits per storage element), voltages stored at the first set of storage elements 106 may be increased without exceeding an upper bound of a voltage window associated with the first set of storage elements 106. Thus, the second data 134 may be folded with respect to the first data 132 to generate the folded data 130 without overwriting the first data 132 (e.g., without exceeding the upper bound of the voltage window associated with the first set of storage elements 106). Additionally, because the folded data 130 is stored as a higher number of bits per storage element than the first data 132, performing the data folding operation increases the number of bits stored per storage element in the first set of storage elements 106.

In a particular implementation, after the second data 134 has been used in the data folding operation, the second data 134 may be obsolete. To re-use the second set of storage elements 108 without performing a full erase operation, a partial erase operation may be performed at the second set of storage elements 108. The partial erase operation may be faster and use a lower voltage than a full erase operation. Partial erase operations are further described with reference to FIGS. 3, 4, and 7.

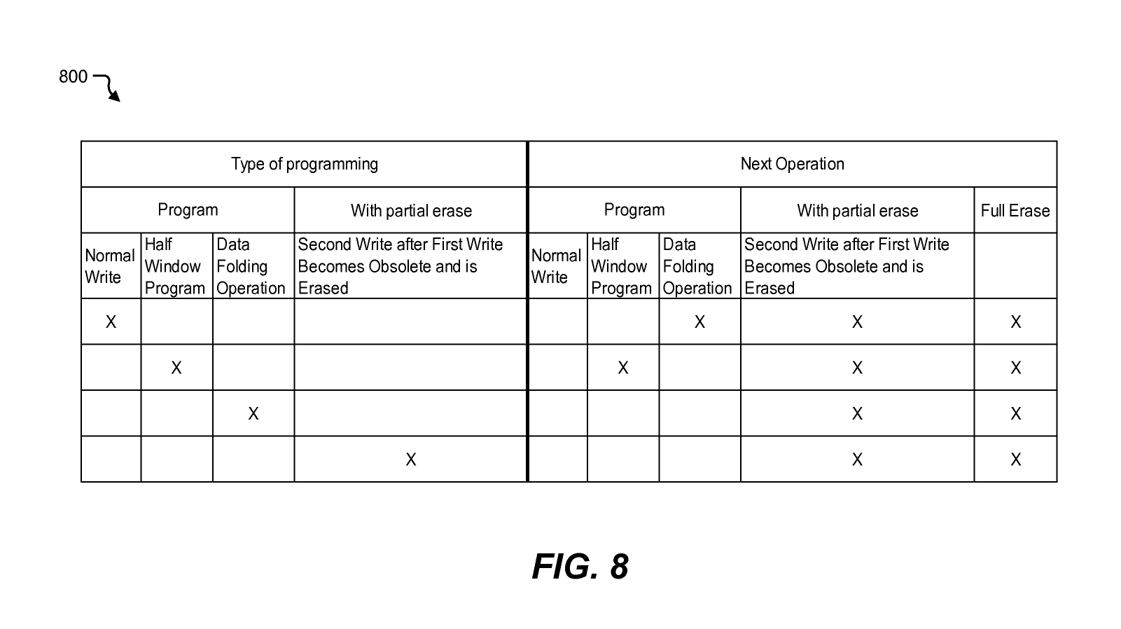

Additionally, the controller 120 may be configured to track which operations are performed to each set of storage elements. For example, the controller 120 may track which operations (e.g., data fold operations, partial erase operations, half-window write operations, etc.) have been performed to the first set of storage elements 106 and the second set of storage elements 108, and to the resultant information as the storage element information 164 in the controller memory 160. In some implementations, the storage element information 164 may be stored to the memory 105 (e.g., before a power-down operation of the controller 120). The storage element information 164 may indicate (or may be used to determine) which operations are permissible to be performed on the first set of storage elements 106 and the second set of storage elements 108, as further described with reference to FIG. 8. The storage element information 164 may also indicate how many bits of data are stored per storage element for each set of storage elements.

A particular implementation of the device 100 includes the access device 150 coupled to the data storage device 102. The data storage device 102 includes the memory device 104 that includes the memory 105. The memory 105 includes the first set of storage elements 106 and the second set of storage elements 108. The data storage device 102 further includes the circuitry 140. The circuitry 140 is coupled to the memory 105 and is configured to perform a data folding operation to fold the second data 134 from the second set of storage elements 108 with respect to the first data 132 stored at the first set of storage element 106. Each storage element of the first set of storage elements 106 is designated to store at least three bits per storage element, and each storage element of the second set of storage elements 108 is designated to store at least two bits per storage element. In at least one implementation, the circuitry 140 is configured to perform the data folding operation by reading the second data 134 from the second set of storage elements into the buffer 142 and by writing the second data 134 from the buffer 142 to the first set of storage elements 106. Folding the second data 134 with respect to the first data 132 increases a number of bits stored in the first set of storage elements 106 without overwriting the first data 132.

Additionally, a method of performing operations at the device 100 may include reading the second data 134 from the second set of storage elements 108 and writing the second data 134 to the first set of storage elements 106. Each storage element of the second set of storage elements 108 is designated to store at least two bits per storage element, and each storage element of the first set of storage elements 106 is designated to store at least three bits per storage element. Writing the second data 134 to the first set of storage elements 106 increases the number of bits stored in each storage element of the first set of storage elements 106. The method may be performed by the memory device 104 which includes the first set of storage elements 106 and the second set of storage elements 108. Writing the second data 134 to the first set of storage elements 106 includes performing a data folding operation. Prior to the data folding operation, each storage element of the first set of storage elements 106 stores k bits per storage element, and each storage element of the second set of storage elements 108 stores i bits per storage element. Subsequent to the data folding operation, each storage element of the first set of storage elements 106 stores k+i bits per storage element.

Thus, the data storage device 102 of FIG. 1 may enable efficient storage of higher level data to a set of storage elements. For example, by using a multi-level write operation to write multi-level data (e.g., X2 data) to the first set of storage elements 106 and the second set of storage elements 108 and performing a data folding operation, the data storage device 102 may operate more efficiently and with higher reliability than data storage devices that write the higher level data (e.g., X4 data) to a set of storage elements using a single higher level data write operation.

Referring to FIG. 3, a diagram 300 illustrating a method of operation of the data storage device 102 of FIG. 1 is illustrated. FIG. 3 illustrates a first example of a method of performing a data folding operation on second multi-level data with respect to first multi-level data. For example, with reference to FIG. 1, the data folding operation may generate (e.g., create) the folded data 130 based on the first data 132 and the second data 134. The method begins with the first data 132 being written to the first set of storage elements 106, and the second data 134 being written to the second set of storage elements 108. For example, with reference to FIG. 1, the encoded write data 153 may be received from the controller 120 and may be stored in the latches 144 as the first data 132 and the second data 134. The first data 132 may be written from the latches 144 to the first set of storage elements 106, and the second data 134 may be written from the latches 144 to the second set of storage elements 108. The first set of storage elements 106 may be designated to store at least three bits per storage element, and the second set of storage elements 108 may be designated to store at least two bits per storage element. As illustrated in FIG. 3, the first data 132 may be k-level (Xk) data (e.g., data stored as k bits per storage element), and the second data 134 may be i-level (Xi) data (e.g., data stored as i bits per storage element). K may be an integer greater than one and i may be an integer greater than one. In a particular example, k and i are two. In other examples, k and i may be greater than two and may be different values.

After performance of the write operations, the second data 134 may be “folded into” the first set of storage elements 106. For example, the second data 134 may be read to the buffer 142, and the second data 134 may be written from the buffer 142 to the first set of storage elements 106 to generate the folded data 130. Generating the folded data 130 does not overwrite the first data, as described with reference to FIG. 1. Until the folded data 130 is generated, the second data 134 may be stored in the second set of storage elements 108 as a backup. After writing the second data 134 to the first set of storage elements 106, the second data 134 stored in the second set of storage elements 108 may be “obsolete.” As used herein, obsolete data may refer to data that is not to be used for any other operations (e.g., that is no longer used as backup or for other purposes). The second data 134 in the second set of storage elements 108 may become obsolete once the data folding operation is complete (e.g., once the folded data 130 is generated).

After performance of the data folding operation, the first set of storage elements 106 stores the folded data 130. As illustrated in FIG. 3, the folded data 130 includes k+i level (X(k+i)) data (e.g., data that is stored as k+i bits per storage element). In a particular example, k is equal to two, i is equal to two (e.g., the first data 132 is stored as two bits per storage element, and the second data 134 is stored as two bits per storage element). In this example, after performing the data folding operation, the folded data 130 is X4 data (e.g., data stored as four bits per storage element). Thus, performing the data folding operation increases the number of bits per stored per storage element in the first set of storage elements 106. Although k and i are described as being two, in other implementations, k and i may be other positive integers greater than two and one, respectively. Writing the first data 132 and the second data 134 and performing the data folding operation on the second data 134 with respect to the first data 132 may be more efficient and may be faster than directly storing X(k+i) data in the first set of storage elements 106. For example, writing X2 data to the first set of storage elements 106 and to the second set of storage elements 108, followed by folding the X2 data to generate the folded X4 data may be faster and may be more efficient than directly programming X4 data at the first set of storage elements 106. Thus, the data storage device 102 that performs the data folding operation described with reference to FIG. 3 may have increased efficiency and may perform faster than devices that directly program higher level data (e.g., data stored as a higher number of bits per storage element).

As further illustrated in FIG. 3, a partial erase operation 302 is performed on the second set of storage elements 108. The partial erase operation 302 may set voltages of the second set of storage elements 108 to a within a voltage range associated with a partial erase state that is different than a voltage range associated with an erase state. Based on the voltage range differences, the partial erase operation 302 may be performed faster and slow wear to storage elements (e.g., may increase longevity of storage elements) as compared to performing a full erase operation. Partial erase operations are described in further detail with reference to FIG. 7.

After performing the partial erase operation on the second set of storage elements 108, additional data is written to the second set of storage elements 108 using a write operation 304. As illustrated in FIG. 3, the additional data may also be Xi data. In other examples, the additional data may be less than i-level data (e.g., less than i bits may be stored per storage element). Because the additional data is stored subsequent to performing the partial erase operation 304, the second set of storage elements 108 is able to be written to twice prior to performing a full erase operation, which may reduce wear on the second set of storage elements 108 as compared to performing a full erase operation between two write operations. If the data stored in the first set of storage elements 106, the data stored in the second set of storage elements 108, or both, becomes obsolete, a full erase operation may be performed on the first set of storage elements 106, the second set of storage elements 108, or both, to erase the obsolete data.

Thus, FIG. 3 illustrates performance of a data folding operation and a partial erase operation. As described above, performing multi-level write operations using lower level data and performing the data fold operation may be more efficient than performing a write operation to store higher level data. Additionally, as described above, performing the partial erase operation may be faster than performing a full erase operation as well as slowing wear to storage elements. Thus, the operations described in FIG. 3 may enable more efficient programming of data and may increase longevity of the memory 105 of FIG. 1.

Referring to FIG. 4, a diagram 400 illustrating a method of operation of the data storage device 102 of FIG. 1 is illustrated. FIG. 4 illustrates a second example of a method of performing a data folding operation on second multi-level data with respect to first multi-level data. For example, with reference to FIG. 1, the data folding operation may generate the folded data 130 based on the first data 132 and the second data 134.

As illustrated in FIG. 4, the first data 132 is written to the first set of storage elements 106 and that the second data 134 is written to the second set of storage elements 108. The first data 132 may be written from the latches 144 to the first set of storage elements 106, and the second data 134 may be written from the latches 144 to the second set of storage elements 108, as described with reference to FIG. 1. As illustrated in FIG. 4, after writing the first data 132 to the first set of storage elements 106, the first set of storage elements 106 stores Xk data, and the second set of storage elements 108 may stores Xh data. In a particular example, k and h are equal to two. In other examples, k and h may be greater than two and may be different numbers.

The write operation of the first data 132 to the first set of storage elements 106 is a “full” write operation (e.g., a “normal” write operation). However, in the implementation illustrated in FIG. 4, the write operation of the second data 134 to the second set of storage elements 108 is a half-window programming operation (e.g., a half-window write operation). The half-window write operation may write data to the second set of storage elements 108 such that states are distributed within a voltage sub-window, as compared to a full write operation, where states are distributed within a voltage window that is larger than the voltage sub-window. Half-window write operations are described in further detail with reference to FIG. 6.

After performance of the write operations, the second data 134 stored in the second set of storage elements 108 is folded with respect to the first data 132 stored in the first set of storage element 106 to generate the folded data 130 of FIG. 1. As described above, the data folding operation increases the number of bits stored per storage element of the first set of storage elements 106. For example, the number of bits stored in the first set of storage elements 106 may be increased from k bits per storage element to k+h bits per storage element as a result of the data folding operation. As explained with reference to FIG. 3, the second data 134 may be stored in the second set of storage elements 108 until the data folding operation is complete. After the data folding operation is complete, the second data 134 stored in the second set of storage elements 108 may become obsolete. At this time, additional data may be written to the second set of storage elements 108 using a second half-window write operation 402.

The second half-window write operation 402 may overwrite the second data 134 with the additional data. Also, the additional data may be written without performance of an erase operation to the second set of storage elements 108. Because the additional data is stored without performing an erase operation, writing the second data 134 and the additional data using half-window write operations may be faster and more efficient than writing data, performing an erase operation, and writing more data. Also, because an erase operation is eliminated (e.g., is not performed between half-window write operations), use of the half-window write operations slows wear to the second set of storage elements 108.

After performance of the data folding operation, the folded data 130 is stored in the first set of storage elements 106. As illustrated in FIG. 4, the folded data includes k+h level data, also referred to as X(k+h) data (e.g., data that is stored as k+h bits per storage element). Additionally, after the additional data stored in the second set of storage elements 108 becomes obsolete, a partial erase operation 404 may be performed on the second set of storage elements 108. The partial erase operation is further described with reference to FIG. 7.

After performance of the partial erase operation 404 at the second set of storage elements 108, second additional data may be written to the second set of storage elements 108 using a write operation 406. As illustrated in FIG. 4, the second additional data may be Xh data. Because the partial erase operation 404 is performed faster, and slows wear on the second set of storage elements 108 as compared to a full erase operation, storing the second additional data to the second set of storage elements 108 after the partial erase operation may be preferable to performing a full erase operation prior to storing the second additional data. Thus, FIG. 4 illustrates performance of operations (e.g., the data folding operation, the partial erase operation, and the half-window write operation) that increase programming efficiency and increase longevity of the memory 105 of FIG. 1.

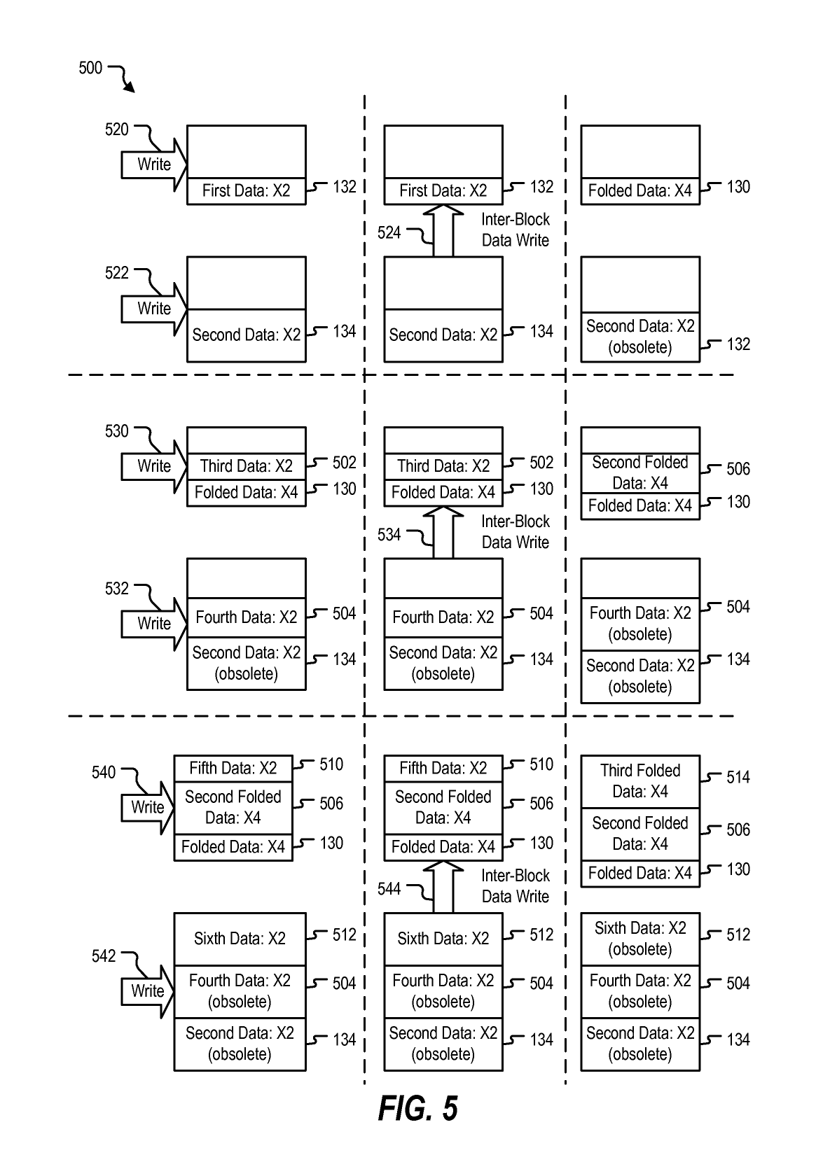

Referring to FIG. 5, a diagram 500 illustrating a method of operation of the data storage device 102 of FIG. 1 is illustrated. FIG. 5 illustrates an example of a method of performing a data folding operation to store fourth level (X4) data. In the example in FIG. 5, second level data (X2 data) is folded into X2 data to generate the X4 data. The particular implementation described with reference to FIG. 5 is illustrative. In other implementations, other levels of multi-level data may be written to the sets of storage elements, which may result in other levels of folded multi-level data. FIG. 5 illustrates an example of writing a particular level of data to a block of a memory. For example, a first block includes the first set of storage elements 106 (e.g., a first word line), and a second block includes the second set of storage elements 108 (e.g., a second word line).

The method includes writing the first data 132 to the first set of storage elements 106 during a first write operation 520 and writing the second data 134 to the second set of storage elements 108 during a second write operation 522. Although described as a single write operation, each multi-level write operation may include one or more write operations. Each of the write operations described with reference to FIG. 5 may be multi-level write operations that write multi-level data to a corresponding set of storage elements. The first write operation 520 may be a full write operation. The second write operation 522 may be a full write operation, or a half-window write operation, as described with reference to FIG. 4.

After writing the first data 132 and the second data 134, the second data 134 is folded into the first data 132 using an inter-block data write operation 524 (e.g., a data folding operation). For example, with reference to FIG. 1, the second data 134 may be read from the second set of storage elements 108 to the buffer 142, and the second data 134 may be written from the buffer 142 to the first set of storage elements 106 by performing the inter-block data write operation 524. The inter-block date write operation 524 may write the second data 134 to the first set of storage elements 106 without overwriting the first data 132. For example, the second data 134 may be folded with respect to the first data 132 to generate the folded data 130. As described with reference to FIG. 1, folding the second data 134 with respect to the first data 132 increases the number of bits of data stored per storage element in the first set of storage elements 106. As a particular example, the second data 134 may be stored two bits per storage element, the first data 132 be stored as two bits per storage element, and the folded data 130 may be stored as four bits per storage element. In other examples, the data levels of the first data 132, the second data 134, and the folded data 130 may be different.

After performance of the inter-block data write operation 524, the first set of storage elements 106 stores the folded data 130, and the second set of storage elements 108 stores the second data 134. After performance of the inter-block data write operation 524, the second data 134 may be obsolete. As described with reference to FIGS. 3 and 4, the second data 134 may be erased using a partial erase operation, may be overwritten using a half-window write operation (if the second write operation 522 is a half-window write operation), or may be maintained until a later time.

Next, the above-described operations are performed at different portions of the first block and the second block. For example, the operations described as performed at the first set of storage elements 106 and the second set of storage elements 108 may be performed at a second portion and a third portion of the first block (e.g., a third word line and a fifth word line), and at a second portion and a third portion of the second block (e.g., a fourth word line and a sixth word line).

To illustrate, third data 502 is written to the second portion of the first block using a write operation 530, and fourth data 504 is written to the second portion of the second block using a write operation 532. The write operations 532 may be a full write operation or a half-window write operation. As illustrated in FIG. 5, the third data 502 and the fourth data 504 are X2 data. After the third data 502 and the fourth data 504 is written, the fourth data 504 is written to the first block using an inter-block data write operation 534. The inter-bock data write operation 534 may be similar to the inter-block data write operation 524. The fourth data 504 may remain stored in the second block, until the inter-block data write operation 534 is complete. After completion of the inter-block data write operation 534, the second portion of the first block stores second folded data (e.g., X4 data). Subsequently, the fourth data 504 may become obsolete. In some implementations, the second portion of the second block may be partially erased or may be programmed with additional data using a half-window write operation (if the write operation 532 is a half-window write operation) to further increase efficiency of data processing.

Next, fifth data 510 is written to the third portion of the first block using write operation 540, and sixth data 512 is written to the third portion of the second block using write operation 542. The write operation 542 may be a full write operation or a half-window write operation. As illustrated in FIG. 5, the fifth data 510 and the sixth data 512 may be X2 data. After the fifth data 510 and the sixth data 512 is written, the sixth data 512 may be folded into the fifth data 510 using an inter-block data write operation 544. The inter-block data write operation 544 may be similar to the inter-block data write operations 524 and 534. After performance of the inter-block data write operation 544, third folded data 514 is stored in the third portion of the first block. After the performance of the three inter-block data write operations 524, 534, and 544, folded data is stored in each storage element of the first block. As illustrated in FIG. 5, the folded data in each of the storage elements of the first block (e.g., the folded data 130, the second folded data 506, and the third folded data 514), may be X4 data. Additionally, after performance of the inter-block data write operation 544, the sixth data 512 stored in the third portion of the second block becomes obsolete. As described above, in some implementations, the sixth data 512 may be erased using a partial erase operation or additional data may be written using a half-window write operation (if the write operation 542 is a half-window write operation).

Thus, FIG. 5 illustrates storing folded data in the first block on a portion by portion basis. Additionally, data from a second block, may be folded into the data written to the first block one portion at a time. In other implementations, data may be written to the entire other divisions of memory. By writing lower level data and performing the data folding operations (e.g., the inter-block data write operations 524, 534 and 544), higher level data may be more efficiently stored in a first block of the memory 105 than directly writing the higher level data to the first block of the memory 105.

Referring to FIG. 6, CVD diagrams that represent states corresponding to storage elements after a first half-window programming operation (also referred to as a first half-window write operation) and after a second half-window programming operation (also referred to as a second half-window write operation) are shown. A first CVD diagram 600 illustrate states of storage elements after the first half-window write operation, and a second CVD diagram 610 illustrates states of storage elements after the second half-window write operation. During a half-window write operation, data may be written to a set of storage elements. However, in contrast to a full write operation (e.g., a “normal” write operation), data is written to the set of storage elements during the half-window programming operation using a lower write voltage than a write voltage associated with a full write operation. To illustrate, in FIG. 6, if a full write operation is performed, states of the set of storage elements after the full write operation may be distributed within a voltage range (e.g., between a lower bound v1 and an upper bound v2) due to application of a full write voltage. As non-limiting examples, v1 may be approximately zero volts and v2 may be approximately six volts. In other implementations, v1 and v2 may be other voltage values.

In contrast to the full write operation, after performing the first half-window write operation, states of the set of storage elements may be distributed within a first voltage sub-range that is smaller than the voltage range. For example, the voltage sub-range may have a lower bound of v1 and an upper bound (e.g., a half-window threshold voltage) labeled Vt in FIG. 6. In some implementations, the voltage sub-range may be approximately half the size of the voltage range associated with the full write operation. In other implementations, the voltage sub-range may be a smaller size, or a larger size, than the voltage range associated with the full write operation. In the example illustrated in FIG. 6, X2 data may be written, and the states of the set of storage elements may be one of four states 602, 604, 606, and 608. In other implementations, the data may be a different level of data, and the number of states may be more than four. For example, the data may be written as three bits per storage element, and the number of states associated with the data may be nine. As another example, the data may be written as four bits per storage element, and the number of states may be sixteen.

As illustrated in FIG. 6, after the first half-window write operation, the states of the set of storage elements may have be distributed within the first voltage sub-range (e.g., a range between v1 and Vt). Thus, each threshold voltage may be less than Vt (e.g., a particular half-window threshold voltage) that is less than v2 (e.g., a particular write threshold voltage or upper bound). After performing a second half-window operation, additional data may be written to the set of storage elements without performing an erase operation. The additional data may be written by application of one or more half-window write voltages to the set of storage elements. Because a second sub-range of voltages (e.g., a range between Vt and v2) was not used by the first half-window write operation, the second half-window write operation may convert the states of the set of storage elements to states within the second sub-range of voltages. Thus, after performance of the second half-window write operation, at least one state may exceed Vt (e.g., a particular half-window threshold voltage). Such conversion may represent storing the additional data by overwriting the previous data. For example, after performing a second half-window write operation, the set of states may be one of states 612, 614, or 616, which represent the additional data. Alternatively, the state may be within the first voltage sub-range (e.g., between v1 and Vt). However, any voltage within the first voltage sub-range represents the erase state after the second half-window write operation. Because the voltages associated with the states 612-616 exceed voltages associated with the states 602-608, the previous data may be converted to the additional data using the second half-window write operation without performing an erase operation.

Thus, two half-window write operations may be performed on a single set of storage elements prior to performing any erase operation. Because erase operations may increase wear on the set of storage elements faster than write operations, performing two half-window write operations prior to performing an erase operation may slow wear to the set to storage elements as compared to performing a write operation, followed by an erase operation, followed by another write operation. Thus, use of half-window write operations may increase longevity of storage elements of the memory 105 of FIG. 1.

Referring to FIG. 7, CVD diagrams that represent states corresponding to storage elements prior to, during, and subsequent to a partial erase operation are shown. The partial erase operation may be performed on sets of storage elements. In a particular implementation, the partial erase operation may be performed on the second set of storage elements 108 of FIG. 1 after the second data 134 becomes obsolete, as described with reference to FIGS. 3 and 4. In other implementations, the partial erase operation may be performed on other sets of storage elements of the memory 105 of FIG. 1.

A first CVD diagram 700 of FIG. 7 illustrates states associated with a set of storage elements prior to performance of a partial erase operation on a set of storage elements. In the example illustrated in FIG. 7, prior to performance of the partial erase operation, the set of storage elements stores X3 data (e.g., data is stored as three bits per storage element). In other implementations, other data (e.g., X2 data, X4 data, etc.) may be stored in the set of storage elements. Because storage of X3 data is illustrated, the first CVD diagram 700 illustrates eight states corresponding to the data, referred to herein as the “previous” data. For example, the previous data may refer to the second data 134, prior to performance of the partial erase operation 302. In FIG. 7, an erase state and states A-G, are distributed within a first voltage range (e.g., a range between a lower bound v1 and an upper bound v2).

A second CVD diagram 702 illustrates states of a set of storage elements after performance of a partial erase operation on the set of storage elements. After performance of the partial erase operation, states of the set of storage elements of set to a partial erase state. The partial erase state has a partial erase state voltage range Er illustrated in the second CVD diagram 702. During a partial erase operation, a partial erase voltage is applied to the set of storage elements to set voltages stored at the set of storage elements to within the partial erase state voltage range represented by the voltage range Er. The partial erase state voltage range Er may encompass a larger range than an erase state voltage range associated with the erase state Erase illustrated in the first CVD diagram 700. Additionally, an upper bound (v_PE) of the partial erase state voltage range is greater than an upper bound of the erase state voltage range. Because v_PE is greater than the upper bound of the erase state threshold voltage range, the partial erase operation may be performed by applying one or more reduced voltages as compared to the full erase operation, and the partial erase operation may be faster than the full erase operation.

A third CVD diagram 704 illustrates a first example of a write operation performed after the partial erase operation on the set of storage elements. In the example illustrated in the third CVD diagram 704, data written to the set of storage elements may be stored as fewer bits per storage element than the previous data (e.g., data written to the set of storage elements prior to the partial erase operation). For example, the set of storage elements may store three bits per storage element prior to the performance of the partial erase operation, and subsequent to the partial erase operation, the set of storage elements may store two bits per storage element.

A fourth CVD diagram 706 illustrates a second example of a write operation performed after the partial erase operation on the set of storage elements. In the example illustrated in the fourth CVD diagram 706, data written to the set of storage elements may be stored as the same number of bits per storage element as the previous data. For example, the set of storage elements may store three bits per storage element prior to the performance of the partial erase operation, and subsequent to the partial erase operation, the set of storage elements also stores three bits per storage element.

In some implementations, storing the same number of bits per storage element after a partial erase may be preferable, in order to increase efficiency of data storage at the set of storage elements. However, because the range of voltages available to store the data (e.g., the range between v_PE and v2) is decreased as compared to the range of voltages available prior to performing the partial erase operation (e.g., the range between v1 and v2), the states may correspond to smaller voltage ranges. Due to the smaller voltage ranges, the data may be associated with a decrease in reliability. To maintain approximately the same level of reliability as before the partial erase operation, less data may be written to the set of storage elements. Alternatively, the same level of data may be written to maintain efficiency, but with reduce reliability. Thus, selection between the examples illustrated in the CVD diagrams 704 and 706 may be based on target reliability levels and target efficiency levels of the memory 105 of FIG. 1.

Performing the partial erase operation may increase the longevity of a set of storage elements as compared to performing a full erase operation. For example, less voltage may be used to set the storage elements to the partial erase state than to the erase state (of the full erase operation). Because the voltage is reduced as compared to the full erase operation, the partial erase operation may slow wear to the set of storage elements as compared to the full erase operation, thus increasing longevity of the memory 105 of FIG. 1. Additionally or alternatively, the voltage applied during the partial erase operation may be for a smaller duration than a voltage applied during a full erase operation. Thus, use of the partial erase operation may increase speed and efficiency of storing data to the memory 105 of FIG. 1.

FIG. 8 depicts a table 800 indicating a next permissible programming operation (e.g., a write operation) or erase operation based on a current operation performed on a set of storage elements. For example, with reference to FIG. 1, the table 800 may correspond to the storage element information 164. The storage element information 164 may indicate a recent write operation or erase operation performed at the first set of storage elements 106 or the second set of storage elements 108, or any other set of storage elements of the memory 105. The storage element information 164 (e.g., the table 800) may be used to determine a permissible next operation to be performed at the first set of storage elements 106 and the second set of storage elements 108.

As illustrated in FIG. 8, any of multiple operations may be performed at a set of storage elements. If a normal write operation (e.g., a full write operation) is performed at the set of storage elements, then a next permissible operation to be performed at the set of storage elements includes a data folding operation, a partial erase operation followed by a second write operation, or a full erase operation. If a half-window programming operation (e.g., a half-window write operation) is performed at the set of storage elements, a next permissible operation to be performed at the set of storage elements includes a second half-window write operation, a partial erase operation followed by a second write operation, or a full erase operation. If a data folding operation is performed at the set of storage elements, a next permissible operation to be performed at the set of storage elements includes a partial erase operation followed by a second write operation, or a full erase operation. If a second write operation (after a partial erase operation) is performed at the set of storage elements, a next permissible operation to be performed at the set of storage elements includes a full erase operation or a partial erase operation followed by a write operation. In a particular implementation, after performance of an operation that programs data (e.g., a full write operation, a half-window write operation, a data folding operation, or a write operation following a partial erase operation) at a set of storage elements, a full erase operation or a partial erase operation (followed by a write operation) may be performed at the set of storage elements.

Although the table indicates four tracked values, the storage element information 164 may include information associated with each set of storage elements of the memory 105. Additionally, although not illustrated, the table 800 may also include a number of bits stored per storage element for each set of storage elements. Thus, FIG. 8 illustrates the storage element information 164 of FIG. 1, which may be used to determine a permissible next operation to be performed at a set of storage elements.

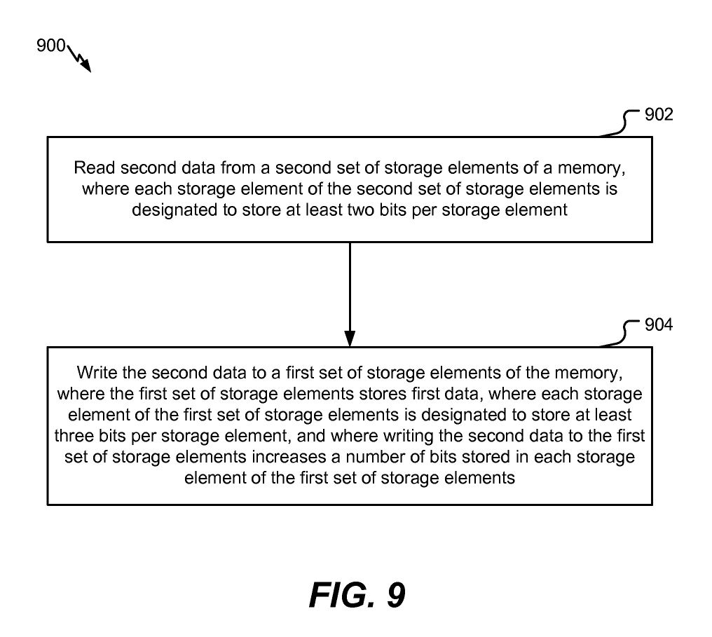

Referring to FIG. 9, a particular illustrative example of a method of performing memory operations is illustrated. The method 900 includes reading second data from a second set of storage elements of a memory where each storage element of the second set of storage elements is designated to store at least two bits per storage element, at 902. For example, the second data 134 may be read from the second set of storage elements 108 of the memory 105. Each storage element of the second set of storage elements 108 is designated to store at least two bits per storage element.

The method 900 further includes writing the second data to a first set of storage elements of the memory, where the first set of storage elements stores first data, where each storage element of the first set of storage elements is designated to store at least three bits per storage element, and where writing the second data to the first set of storage elements increases a number of bits stored in each storage element of the first set of storage elements, at 904. For example, the second data 134 may be written to the first set of storage elements 106 of the memory 105. The first set of storage elements 106 stores the first data 132, and each storage element of the first set of storage elements 106 is designated to store at least three bits per storage element. Writing the second data 134 to the first set of storage elements 106 (e.g., during a data folding operation) increases a number of bits stored in each storage element of the first set of storage elements 106, as described with respect to FIG. 1.

Thus, by performing two write operations and performing a data folding operation, write processing speed is increased and reliability may also be increased. For example, efficiency is increased by writing first data (stored as two bits per storage element) to a first storage element and second data (stored as two bits per storage element) to a second storage element, and then performing a data folding operation on the first data and the second data, as compared to performing a direct write of data (stored as four bits per storage element) to the storage element.

In some implementations, the method 900 may include additional memory operations. For example, the method 900 may further include, subsequent to receiving a write command at the memory, receiving write data and storing a first portion of the write data to latches, writing the first portion of the write data from the latches to the first set of storage elements as first data, storing a second portion of the write data in the latches, and writing the second portion of the write data from the latches to the second set of storage elements as second data. Writing the second data to the first set of storage elements is performed subsequent to writing the second data to the second set of storage elements. For example, the encoded write data 153 may be received (as part of a write command) from the controller 120 at the memory device 104, and a first portion of the encoded write data 153 may be stored in the latches 144 as the first data 132. Additionally, a second portion of the encoded write data 153 may be stored in the latches 144 as the second data 134. The first data 132 may be written from the latches 144 to the first set of storage elements 106, and the second data 134 may be written from the latches 144 to the second set of storage elements 108. Writing the second data 134 to the first set of storage elements 106 (e.g., by performing the data folding operation) is performed subsequent to writing the second data 134 to the second set of storage elements 108.

The method 900 may further include additional processing steps, such as performing a partial erase operation to set voltages corresponding to the second set of storage elements to within a partial erase state voltage range, where an upper bound of the partial erase state voltage range is less than an upper bound of an erase state voltage range. For example, performing the partial erase operation may set voltages of a set of storage elements (e.g., the second set of storage elements 108) to within a partial erase state voltage range Er illustrated in the second CVD diagram 702 of FIG. 7.

In addition, the method 900 may include writing third data to the second set of storage elements prior to performing an erase operation to set the voltages corresponding to the second set of storage elements to within an erase state voltage range, where each storage element of the second set of storage elements stores the same number of bits per storage element prior to writing the third data and after the writing the third data. For example, prior to performing a full erase operation, third data having the same number of bits per storage element as previous data may be written to the second set of storage elements 108, as represented by the fourth CVD diagram 706 of FIG. 7. Alternatively, the method 900 may further include writing third data to the second set of storage elements prior to performing an erase operation to set the voltages corresponding to the second set of storage elements to within an erase state voltage range, where each storage element of the second set of storage elements stores fewer bits per storage element after writing the third data (as compared to prior to writing the third data). For example, prior to performing a full erase operation, third data having fewer bits per storage element as previous data may be written to the second set of storage elements 108, as represented by the third CVD diagram 704 of FIG. 7.

The method 900 may also include writing the second data to the second set of storage elements using a half-window write operation, where, subsequent to the half-window write operation, each voltage corresponding to the second set of storage elements is less than a particular half-window write threshold voltage that is less than a particular write voltage threshold value. For example, subsequent to performing a first half-window write operation, the second set of storage elements 108 may have voltages selected from within voltage ranges associated with the states 602-608 of FIG. 6. The states 602-608 are less than a particular half-window write threshold voltage (Vt) that is less than a particular write threshold voltage (v2). Additionally, the method 900 may further include writing third data to the second set of storage elements using a second half-window write operation prior to performing any erase operation at the second set of storage elements, where, subsequent to the second half-window write operation, at least one voltage corresponding to the second set of storage elements exceeds the particular half-window write threshold voltage. For example, subsequent to performing a second half-window write operation, the second set of storage elements 108 may have voltages selected from within the voltage ranges associated with the states 612-616 of FIG. 6. The voltages may exceed the particular half-window threshold voltage (Vt).

The method 900 may also include maintaining storage element information for the first set of storage elements and the second set of storage elements, where the storage element information indicates a number of bits stored per storage element, a recent operation performed at a corresponding set of storage elements, or a combination thereof. For example, the storage element information 164 may indicate a number of bits stored per storage element for a corresponding set of storage elements, a recent operation performed at a corresponding set of storage elements, or a combination thereof, as described with reference to FIG. 8.

The method 900 of FIG. 9 may be initiated or controlled by an application-specific integrated circuit (ASIC), a processing unit, such as a central processing unit (CPU), a controller, another hardware device, a firmware device, a field-programmable gate array (FPGA) device, or any combination thereof. As an example, method 900 of FIG. 9 can be initiated or controlled by one or more processors, such as one or more processors included in or coupled to a controller or a memory of the data storage device 102 and/or the access device 150 of FIG. 1. As an example, the method 900 of FIG. 9, individually or in combination, may be performed by the controller 120 of FIG. 1. To illustrate, a portion of the method FIG. 9 may be combined with other operations described herein. Additionally, one or more operations described with reference to the FIG. 9 may be optional, may be performed at least partially concurrently, and/or may be performed in a different order than shown or described.

In an illustrative example, a processor may be programmed to perform a data folding operation on second data with respect to first data to generate folded data. For example, the processor may execute instructions to read second data from a second set of storage elements of a memory. Each storage element of the second set of storage elements is designated to store at least two bits per storage element. The processor may further execute instructions to write the second data to a first set of storage elements of the memory. The first set of storage elements stores first data. Each storage element of the first set of storage elements is designated to store at least three bits per storage element, and writing the second data to the first set of storage elements increases a number of bits stored in each storage element of the first set of storage elements.

In conjunction with the described aspects, a device includes means for storing first data read from a first set of storage elements of a memory, where each storage element of the first set of storage elements is designated to store at least two bits per storage element. The means for storing first data may include or correspond to the buffer 142 of FIG. 1, one or more other structures or circuits configured to store first data read from a first set of storage elements of a memory, or any combination thereof.

The device further includes means for writing the first data to a second set of storage elements, where each storage element of the second set of storage elements is designated to store at least three bits per storage element, and where writing the first data to the second set of storage elements increases a number of bits stored in each storage element of the second set of storage elements. The means for writing the first data may include or correspond to the circuitry 140 of FIG. 1, one or more other structures or circuits configured to write the first data to the second set of storage elements, or any combination thereof.

In a particular implementation, the device may further include means for receiving write data, where a first portion of the write data is stored in the first set of storage elements as the first data, and where a second portion of the write data is stored in the second set of storage elements as second data. The means for receiving write data may include or correspond to the latches 144 of FIG. 1, one or more other structures or circuits configured to receive the write data, or any combination thereof.

Although various components of the data storage device 102 and/or the access device 150 of FIG. 1 are depicted herein as block components and described in general terms, such components may include one or more microprocessors, state machines, or other circuits configured to enable the various components to perform operations described herein. One or more aspects of the various components may be implemented using a microprocessor or microcontroller programmed to perform operations described herein, such as one or more operations of the method 900 of FIG. 9. In a particular implementation, each of the controller 120, the memory device 104, the memory 105, the controller memory 160, and/or the access device 150 of FIG. 1 includes a processor executing instructions that are stored at a memory, such as a non-volatile memory of the data storage device 102 or the access device 150 of FIG. 1. Alternatively or additionally, executable instructions that are executed by the processor may be stored at a separate memory location that is not part of the non-volatile memory, such as at a read-only memory (ROM) of the data storage device 102 or the access device 150 of FIG. 1.

With reference to FIG. 1, the data storage device 102 may be attached to or embedded within one or more access devices, such as within a housing of a communication device (e.g., the access device 150). For example, the data storage device 102 may be integrated within an apparatus, such as a mobile telephone, a computer (e.g., a laptop, a tablet, or a notebook computer), a music player, a video player, a gaming device or console, an electronic book reader, a personal digital assistant (PDA), a portable navigation device, a system integrated within a vehicle, such as a console display unit, or other device that uses non-volatile memory. However, in other embodiments, the data storage device 102 may be implemented in a portable device configured to be selectively coupled to one or more external access devices. In still other embodiments, the data storage device 102 may be a component (e.g., a solid-state drive (SSD)) of a network accessible data storage system, such as an enterprise data system, a network-attached storage system, a cloud data storage system, etc.

To further illustrate, the data storage device 102 may be configured to be coupled to the access device 150 as embedded memory, such as in connection with an embedded MultiMedia Card (eMMC®) (trademark of JEDEC Solid State Technology Association, Arlington, Va.) configuration, as an illustrative example. The data storage device 102 may correspond to an eMMC device. As another example, the data storage device 102 may correspond to a memory card, such as a Secure Digital (SD®) card, a microSD® card, a miniSD™ card (trademarks of SD-3C LLC, Wilmington, Del.), a MultiMediaCard™ (MMC™) card (trademark of JEDEC Solid State Technology Association, Arlington, Va.), or a CompactFlash® (CF) card (trademark of SanDisk Corporation, Milpitas, Calif.). The data storage device 102 may operate in compliance with a JEDEC industry specification. For example, the data storage device 102 may operate in compliance with a JEDEC eMMC specification, a JEDEC Universal Flash Storage (UFS) specification, one or more other specifications, or a combination thereof. In yet another particular implementation, the data storage device 102 is coupled to the access device 150 indirectly, e.g., via a network. For example, the data storage device 102 may be a network-attached storage (NAS) device or a component (e.g., a solid-state drive (SSD) device) of a data center storage system, an enterprise storage system, or a storage area network.

The memory 105 and/or the controller memory 160 of FIG. 1 may include a resistive random access memory (ReRAM), a three-dimensional (3D) memory, a flash memory (e.g., a NAND memory, a NOR memory, a single-level cell (SLC) flash memory, a multi-level cell (MLC) flash memory, a divided bit-line NOR (DINOR) memory, an AND memory, a high capacitive coupling ratio (HiCR) device, an asymmetrical contactless transistor (ACT) device, or another flash memory), an erasable programmable read-only memory (EPROM), an electrically-erasable programmable read-only memory (EEPROM), a read-only memory (ROM), a one-time programmable memory (OTP), or a combination thereof. Alternatively, or in addition, the memory 105 and/or the controller memory 160 may include another type of memory. The memory 105 and/or the controller memory 160 of FIG. 1 may include a semiconductor memory device.

Semiconductor memory devices include volatile memory devices, such as dynamic random access memory (“DRAM”) or static random access memory (“SRAM”) devices, non-volatile memory devices, such as magnetoresistive random access memory (“MRAM”), resistive random access memory (“ReRAM”), electrically erasable programmable read only memory (“EEPROM”), flash memory (which can also be considered a subset of EEPROM), ferroelectric random access memory (“FRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse, phase change material, etc., and optionally a steering element, such as a diode, etc. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND memory array may be configured so that the array is composed of multiple strings of memory in which a string is composed of multiple memory elements sharing a single bit line and accessed as a group. Alternatively, memory elements may be configured so that each element is individually accessible, e.g., a NOR memory array. NAND and NOR memory configurations are exemplary, and memory elements may be otherwise configured.

The semiconductor memory elements located within and/or over a substrate may be arranged in two or three dimensions, such as a two dimensional memory structure or a three dimensional memory structure. In a two dimensional memory structure, the semiconductor memory elements are arranged in a single plane or a single memory device level. Typically, in a two dimensional memory structure, memory elements are arranged in a plane (e.g., in an x-z direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three dimensional memory array is arranged so that memory elements occupy multiple planes or multiple memory device levels, thereby forming a structure in three dimensions (i.e., in the x, y and z directions, where the y direction is substantially perpendicular and the x and z directions are substantially parallel to the major surface of the substrate). As a non-limiting example, a three dimensional memory structure may be vertically arranged as a stack of multiple two dimensional memory device levels. As another non-limiting example, a three dimensional memory array may be arranged as multiple vertical columns (e.g., columns extending substantially perpendicular to the major surface of the substrate, i.e., in the y direction) with each column having multiple memory elements in each column. The columns may be arranged in a two dimensional configuration, e.g., in an x-z plane, resulting in a three dimensional arrangement of memory elements with elements on multiple vertically stacked memory planes. Other configurations of memory elements in three dimensions can also constitute a three dimensional memory array.

By way of a non-limiting example, in a three dimensional NAND memory array, the memory elements may be coupled together to form a NAND string within a single horizontal (e.g., x-z) memory device levels. Alternatively, the memory elements may be coupled together to form a vertical NAND string that traverses across multiple horizontal memory device levels. Other three dimensional configurations can be envisioned wherein some NAND strings contain memory elements in a single memory level while other strings contain memory elements which span through multiple memory levels. Three dimensional memory arrays may also be designed in a NOR configuration and in a ReRAM configuration.

Typically, in a monolithic three dimensional memory array, one or more memory device levels are formed above a single substrate. Optionally, the monolithic three dimensional memory array may also have one or more memory layers at least partially within the single substrate. As a non-limiting example, the substrate may include a semiconductor material such as silicon. In a monolithic three dimensional array, the layers constituting each memory device level of the array are typically formed on the layers of the underlying memory device levels of the array. However, layers of adjacent memory device levels of a monolithic three dimensional memory array may be shared or have intervening layers between memory device levels.

Alternatively, two dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three dimensional memory arrays. Further, multiple two dimensional memory arrays or three dimensional memory arrays (monolithic or non-monolithic) may be formed on separate chips and then packaged together to form a stacked-chip memory device.

Associated circuitry is typically used for operation of the memory elements and for communication with the memory elements. As non-limiting examples, memory devices may have circuitry used for controlling and driving memory elements to accomplish functions such as programming and reading. This associated circuitry may be on the same substrate as the memory elements and/or on a separate substrate. For example, a controller for memory read-write operations may be located on a separate controller chip and/or on the same substrate as the memory elements.

One of skill in the art will recognize that this disclosure is not limited to the two dimensional and three dimensional illustrative structures described but cover all relevant memory structures within the scope of the disclosure as described herein and as understood by one of skill in the art. The illustrations of the embodiments described herein are intended to provide a general understanding of the various embodiments. Other embodiments may be utilized and derived from the disclosure, such that structural and logical substitutions and changes may be made without departing from the scope of the disclosure. This disclosure is intended to cover any and all subsequent adaptations or variations of various embodiments. Those of skill in the art will recognize that such modifications are within the scope of the present disclosure.

The above-disclosed subject matter is to be considered illustrative, and not restrictive, and the appended claims are intended to cover all such modifications, enhancements, and other embodiments, that fall within the scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A device comprising:
a memory including a first set of storage elements and a second set of storage elements; and
circuitry coupled to the memory and configured to perform a data folding operation to fold second data from the second set of storage elements with respect to first data stored at the first set of storage elements, wherein each storage element of the first set of storage elements is designated to store at least three bits per storage element, and wherein each storage element of the second set of storage elements is designated to store at least two bits per storage element.

2. The device of claim 1, further comprising a buffer, wherein the circuitry is configured to perform the data folding operation by reading the second data from the second set of storage elements into the buffer and by writing the second data from the buffer to the first set of storage elements, the second data written to the first set of storage elements without overwriting the first data.

3. The device of claim 1, wherein folding the second data with respect to the first data increases a number of bits stored in the first set of storage elements.

4. The device of claim 1, further comprising latches configured to store a first portion of data received at the memory, and wherein the circuitry is configured to write the first portion of data to the first set of storage elements as the first data.

5. The device of claim 1, further comprising a controller coupled to the memory, wherein the controller is configured to send write data to the memory.

6. The device of claim 1, wherein the first set of storage elements are accessible via a first word line of the memory, and wherein the second set of storage elements are accessible via a second word line of the memory.

7. The device of claim 1, wherein the circuitry comprises read/write circuitry.

8. A method comprising:
at a device including a memory, wherein the memory includes a first set of storage elements and a second set of storage elements, and wherein the first set of storage elements stores first data, performing:
reading second data from the second set of storage elements, wherein each storage element of the second set of storage elements is designated to store at least two bits per storage element; and
writing the second data to the first set of storage elements, wherein each storage element of the first set of storage elements is designated to store at least three bits per storage element, and wherein writing the second data to the first set of storage elements increases a number of bits stored in each storage element of the first set of storage elements.

9. The method of claim 8, wherein writing the second data to the first set of storage elements comprises performing a data folding operation, wherein, prior to the data folding operation, each storage element of the first set of storage elements stores k bits per storage element and each storage element of the second set of storage elements stores i bits per storage element, and wherein, subsequent to the data folding operation, each storage element of the first set of storage elements stores k+i bits per storage element.

10. The method of claim 9, wherein performing the data folding operation does not override the first data.

11. The method of claim 8, further comprising:
subsequent to receiving a write command at the memory, receiving write data and storing a first portion of the write data in latches;
writing the first portion of the write data from the latches to the first set of storage elements as the first data;
storing a second portion of the write data in the latches; and
writing the second portion of the write data from the latches to the second set of storage elements as the second data, wherein writing the second data to the first set of storage elements is performed subsequent to writing the second data to the second set of storage elements.

12. The method of claim 8, further comprising performing a partial erase operation to set voltages corresponding to the second set of storage elements to within a partial erase state voltage range, wherein an upper bound of the partial erase state voltage range is less than an upper bound of an erase state voltage range.

13. The method of claim 12, further comprising writing third data to the second set of storage elements prior to performing an erase operation to set the voltages corresponding to the second set of storage elements to within an erase state voltage range, wherein each storage element of the second set of storage elements stores the same number bits per storage element prior to writing the third data and after writing the third data.

14. The method of claim 12, further comprising writing third data to the second set of storage elements prior to performing an erase operation to set the voltages corresponding to the second set of storage elements to within an erase state voltage range, wherein each storage element of the second set of storage elements stores fewer bits per storage element after the third data as compared to prior to writing the third data.

15. The method of claim 8, further comprising writing the second data to the second set of storage elements using a half-window write operation, wherein, subsequent to the half-window write operation, each voltage corresponding to the second set of storage elements is less than a particular half-window write threshold voltage that is less than a particular write threshold voltage.

16. The method of claim 15, further comprising writing third data to the second set of storage elements using a second half-window write operation prior to performing any erase operation at the second set of storage elements, wherein, subsequent to the second half-window write operation, at least one voltage corresponding to the second set of storage elements exceeds the particular half-window write threshold voltage.

17. The method of claim 8, further comprising maintaining storage element information for the first set of storage elements and the second set of storage elements, wherein the storage element information indicates a number of bits stored per storage element, a recent operation performed at a corresponding set of storage elements, or a combination thereof.

18. A device comprising:
means for storing first data read from a first set of storage elements of a memory, wherein each storage element of the first set of storage elements is designated to store at least two bits per storage element; and
means for writing the first data to a second set of storage elements, wherein each storage element of the second set of storage elements is designated to store at least three bits per storage element, and wherein writing the first data to the second set of storage elements increases a number of bits stored in each storage element of the second set of storage elements.

19. The device of claim 18, further comprising means for receiving write data, wherein a first portion of the write data is stored in the first set of storage elements as the first data, and wherein a second portion of the write data is stored in the second set of storage elements as second data.

20. The device of claim 18, wherein the means for storing comprises a buffer.
